(19) United States
(12) Patent Application Publication
(10) Pub. No.: US 2007/0148951 A1
(43) Pub. Date: Jun. 28, 2007

(54) System and method for flip chip substrate pad

(76) Inventors: Mengzhi Pang, Phoenix, AZ (US); Omar J. Bchir, Chandler, AZ (US)

Correspondence Address: BUCKLEY, MASCHOFF & TALWALKAR LLC, 50 LOCUST AVENUE, NEW CANAAN, CT, 06840, US

(21) Appl. No.: 11/318,840

(22) Filed: Dec. 27, 2005

(51) Int. Cl. H01L 21/44

(52) U.S. Cl. 438/614

(57) ABSTRACT

According to some embodiments, a method, a system, and an apparatus to provide a flip chip conductive bump pad that has a dome shaped area. In some embodiments, the method includes providing a substrate having a conductive bump pad on a first surface of the substrate and forming a dome shaped conductive area on a center area of the conductive bump pad.

### BACKGROUND

Regarding semiconductor devices, there is a desire to increase interconnect density and electrical performance of IC packages. For example, there is a push to provide flip chips having ever smaller bump pitch. Flip chip technologies, including “Controlled Collapse Chip Connection” (C4) applications, may provide a proven mechanism for electrically connecting a die to a mounting substrate. Regarding flip chips, a conductive solder bump is placed directly on a surface of the die. The solder bump offers improved electrical characteristics versus wire bonding techniques.

Reliability of a flip chip may be impacted by the construction of the solder bumps and other assembly factors. Solder joint degradation or failure may result in failure of a flip chip device. A high reliability solder bump interconnection between the solder bump and the die may improve the reliability of the flip chip.

### BRIEF DESCRIPTION OF THE DRAWINGS

FIG. 1 is a flow chart of an exemplary process, in accordance with some embodiments herein;

FIGS. 2A-2F are exemplary illustrations of an apparatus, at various stages of a manufacturing process, according to some embodiments hereof; and

FIGS. 3A-3C are exemplary illustrations of an apparatus, at various stages of a manufacturing process, according to some embodiments hereof;

FIG. 4 is an exemplary illustration of an apparatus, in accordance with some embodiments herein; and

FIG. 5 is an exemplary system, according to some embodiments hereof.

### DETAILED DESCRIPTION

The several embodiments described herein are solely for the purpose of illustration. Embodiments may include any currently or hereafter-known versions of the elements described herein. Therefore, persons in the art will recognize from this description that other embodiments may be practiced with various modifications and alterations.

Some embodiments hereof provide a manufacturing process for producing a flip chip package. In some embodiments, the flip chip is formed using a wafer substrate that has a conductive bump pad on a surface of the substrate. The conductive bump pad (i.e., bump zone) is formed to have a convex or dome shape. The dome shaped conductive bump pad provides a solder wettable area to connect a solder bump to the substrate.

The dome shaped conductive bump pad may provide a bump site having an increased wettability as compared to a flat, planar bump site or pad. In some embodiments, the conductive bump pad is a metal pad. The particular metal may be selected in consideration of a number of electrical, chemical, and processing properties of the metal.

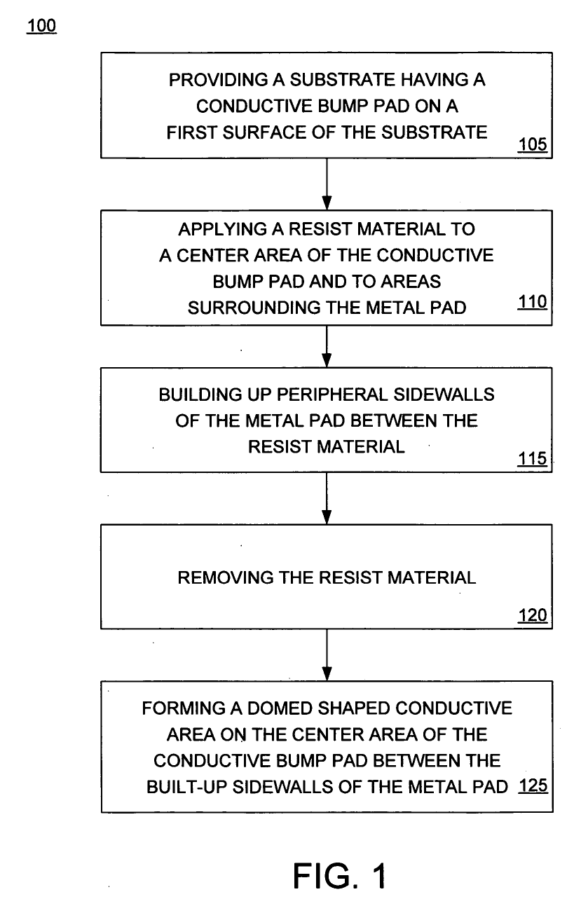

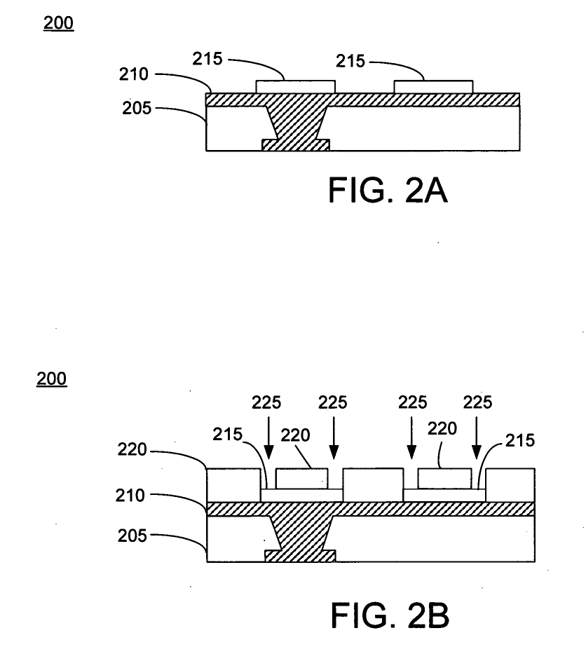

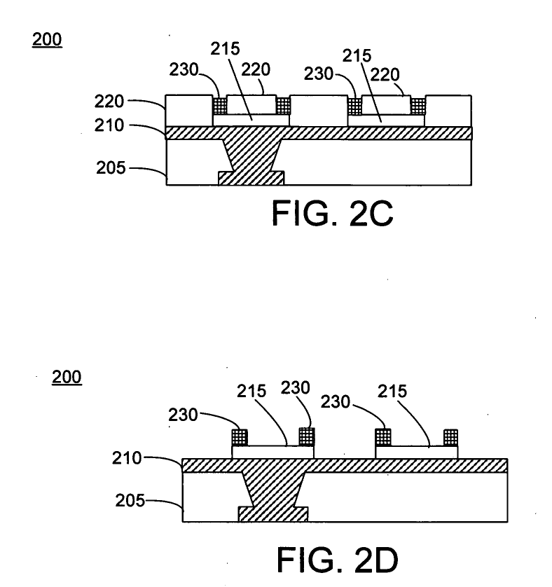

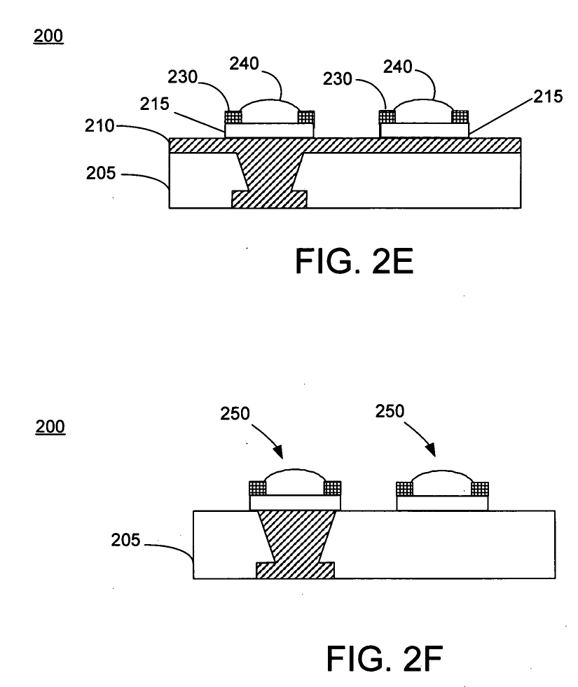

Referring to FIG. 1, there is shown an exemplary flow diagram of a manufacturing process for producing an apparatus having a dome shaped conductive bump pad in accordance with some embodiments hereof, generally represented by the reference numeral 100. Process 100 may be performed by any combination of hardware, software, and/or firmware. According to some embodiments, instructions for implementing process 100 may be stored in executable code. The code may be stored on any suitable article or medium that is or becomes known. Process 100 may be further understood by also referring to FIGS. 2A-2F in conjunction with the following discussion of the flow diagram of FIG. 1.

Initially, at 105, a wafer 200 including a substrate 205 having conductor layer 210 on a first surface of substrate 205 is created, obtained, or otherwise provided for use in process 100. Substrate 205 may be produced or formed using any number of methods of IC (integrated circuit) manufacturing processes that result in a substrate suitable and compatible with the various aspects and embodiments herein. FIG. 2A provides an exemplary illustration of a substrate 205 described at 105, including conductor layer 210 on a top surface of the substrate. In some embodiments, conductor layer 210 may include one or more levels of conductor material.

Additionally, a conductive bump pad 215 is provided in two locations on substrate 205. In some embodiments the bump pad is comprised of a metal.

The conductive bump pad may include a number of metals, alloys, and other conductive materials. In some embodiments, bump pad 215 is made of copper (Cu) disposed on top of substrate 205. In FIG. 2A, two conductive bump pads 215 are shown for illustrative purposes. It is noted that any number and plurality of conductive bump pads 215 may be included on substrate 205 and arranged in a variety of configurations. The variety of arrangements for the plurality of conductive bump pads 215 may be correspond to solder bump configurations for a variety IC manufacturing process constraints and specifications.

In some embodiments, substrate 205 may include a single or multilayer dielectric material. The dielectric material may be selected to include any number of materials compatible with and suitable for IC manufacturing processes, not limited to those explicitly discussed herein. Furthermore, those skilled in the art are familiar with the range of substrate materials compatible with the various embodiments herein. In some embodiments, substrate 205 may include build-up layers of ABF (Ajinomoto Build-Up Film) or other organic film layer.

At 110, substrate 205 is processed to apply a resist material to a center area of the conductive bump pads 215 and the areas surrounding the bump pads. Wafer 200 is processed through an IC manufacturing flow, conventional or otherwise, to pattern a resist layer 220 on top of conductor layer 210, in the center of the conductive bump pads 215 and the areas surrounding the conductive bump pads.

FIG. 2B illustratively depicts wafer 200 having a patterned resist material 220 applied thereto. As shown, substrate 205 includes conductor layer 210, including bump pads 215. The resist material is shown placed on top of and in the center of conductive bump pads 215 and the adjacent areas surrounding conductive bump pads 215. Resist material 220 is applied in a sufficient layer(s) to form vias 225 along a peripheral edge of the bump pads 215. Vias 225 are formed in openings between the built-up layer(s) of resist material 220 located in the center of conductive bump pads 215 and the adjacent areas surrounding the bump pads.

It should be appreciated that resist material 220 should be compatible with IC manufacturing processes and the various embodiments herein. In some embodiments, the resist material may include a dry film resist material.

Vias 225, in some embodiments, may be about 5-10 μm thick.

At 115, illustrated pictorially in FIG. 2C, peripheral sidewalls of the bump pads between resist are formed. Peripheral sidewalls 230 may be formed by an electroplating process in the vias (See FIG. 2B, 225) formed between the built-up layer(s) of resist material 220 located in the center of conductive bump pads 215 and the adjacent areas surrounding the conductive bump pads. Materials suitable for building-up the peripheral walls of bump pads 215 may include, for example, copper.

At operation 120, resist material 220 is selectively removed from the conductive surfaces of wafer 200. In particular, resist material 220 is removed from conductor layer 210 and conductive bump pads 215, as illustrated in FIG. 2D. In accordance with some embodiments herein, wafer 200 at this stage of processing includes substrate 205 with conductive bump pads 215. Conductive bump pads 215 have built-up sidewalls 230 along peripheral edges thereof.

At 125, a dome shaped conductive area is formed on conductive bump pads 215 in the center area of the bump pads between sidewalls 230. As illustrated in FIG. 2E, a dome shaped conductive area 240 is shown formed in the center of each of bump pads 215, in the area between the sidewalls 230. In some embodiments, dome shaped conductive areas 240 have a substantially convex shaped upper surface that extends up and away from the underlying substrate 205. In some embodiments, an upper surface of dome shaped conductive areas 240 extends, in a dome shape configuration, above the surrounding sidewalls 230. In some embodiments, the dome shaped conductive area 240 may be formed using an IC manufacturing plating process in the vias formed by the sidewalls 230.

FIG. 2F, is an exemplary illustration of a substrate 205 having two conductive bump pads 250 formed on a surface thereof. The conductive layer(s) 210 shown in prior stages of processing, such as FIGS. 2A-2E, are not present in FIG. 2F. The undesired areas of conductor material may be selectively removed by IC manufacturing processes compatible with the various aspects of the embodiments herein. For example, conductor material 210 in areas other than conductive bump pads 250 may be removed using a wet etch, a quick etch, and other IC processing methods and techniques.

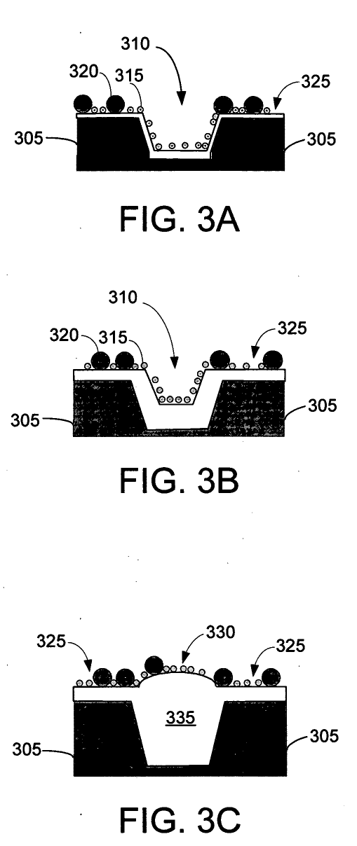

In some embodiments, deposition of conductive materials to form the dome shaped conductive areas 240 (FIG. 2E) and 250 (FIG. 2F) may be accomplished by controlling, in a plating process, the plating chemistry in the vias formed in the center of the conductive bump pads between the built-up sidewalls. For example, the plating process may include using a plating solution having a relatively low concentration of leveler. Referring to FIG. 3A at some initial stages of filling a via 310 formed between sidewalls 305, a concentration of brightener 315 (i.e., anti-suppressor) of a plating solution is substantially the same across the entire via. Large, mass-transfer controlled leveler (i.e., suppressor) 320 molecules that counteract the effect of brightener 315 are concentrated at the upper plating surface 325 at the top of via 310 due to the controller leveler molecules 320 inability to easily transport to the bottom of via 310. The competing effect of leveler 320 and brightener 315 leads to a relatively slower deposition rate on plating surface 325 while the brightener at the via bottom accelerates Cu (or other conductive material) deposition in the via. The competing effects of brightener 315 and leveler 320 may result in a bottom-up fill behavior.

As the deposition continues in FIG. 3B at an interim stage of filling the via, the surface area in the interior of the via decreases. For a fixed number of brightener molecules 315 in via 310, decreasing the Cu surface area may lead to increasing surface concentration of brightener 315 in the via. The deposition rate in via 310 is thus increased relative to the flat plating surface 325. By controlling the plating process such that an inadequate (or reduced) concentration of leveler 320 is available to slow the deposition rate as the fill of via 310 approaches the flat Cu surface 325, the via fill will overshoot the planar Cu surface 325. In this manner, a domed shape conductive area 330 may be formed on conductive bump pad 335 by controlling the chemistry of the plating process.

It should be appreciated that other methods of conductor deposition and conductor formation may be used to produce the dome shaped area on the conductive bump pads herein. Also, although the conductor material discussed in connection with the exemplary illustrations of FIGS. 2A-2F and 3A-3C is discussed as being Cu, it should be noted that other materials such as, for example, Al, other metals, and alloys may be used in some embodiments herein.

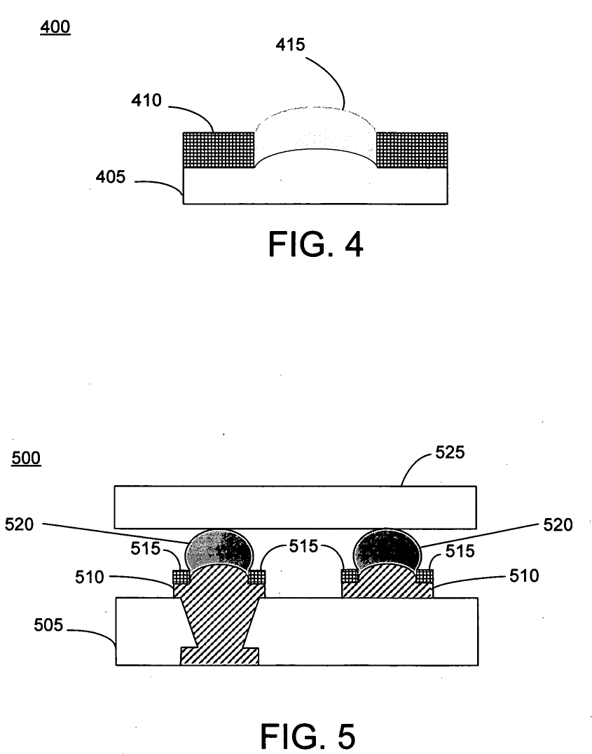

FIG. 4 is an exemplary depiction of an apparatus having a dome shaped conductive bump pad, in accordance with some embodiments herein. A conductive bump pad 405 having a convex, domed shaped upper surface is illustrated. On top of dome shaped conductive bump pad 405 is a quantity of solder 415. Solder 415 may be of the type used in flip chip manufacturing processes and applications. Solder 415 is shown on top of the dome shaped conductive bump pad 405, wherein the extent of solder 415 located on dome shaped conductive bump pad 415 corresponds with the curved features of the dome shaped conductive bump pad 405.

In some embodiments, solder resist 410 may assist in containing solder 415 in an area coinciding with the curved features of dome shaped conductive bump pad 405. In some aspects, the solder resist opening formed in solder 415 is about 70 micrometers (μm) or less in diameter. In some embodiments herein, a size of a solder resist opening may be maintained and yet an increase in solder bump adhesion may be improved by inclusion of the dome shaped conductive pad. The dome shaped conductive pad may provide an increased wettable area for adhesion of the solder to the bump pad.

FIG. 5 is an exemplary depiction of a system, for example a flip chip IC package, including an apparatus having a dome shaped conductive bump pad, in accordance with some embodiments herein. In particular, a substrate 505 has dome shaped conductive bump pads 510 on a surface thereof. The dome shaped aspects of the conductive bump pads are located substantially in a center area of the conductive bump pad. A solder resist opening is formed in solder resist material 515 that is located adjacent to and surrounding conductive bump pads 510. In some embodiments, the solder resist opening is located above the center area of the conductive bump pad 510. A solder bump 520 is located above conductive bump pad 510.

In some embodiments, solder bump 520 may be formed by placing (e.g., printing) a quantity of solder paste in the solder resist opening and reflowing the solder paste in an IC manufacturing process flow. However, other processes and techniques of forming solder bumps 520 (i.e., bumping) may be used.

As further shown in FIG. 5, an IC device 525 is placed in contact with solder bumps 520. IC device 525 may contact solder bumps 520 at conductive connectors, pads, and traces (not shown) to provide electrical connectivity between IC device 525 and substrate 505, through solder bumps 520. In some embodiments, an apparatus, system, and device including the dome shaped conductive pad herein may contribute to an increase in yield in a manufacturing process and/or an increase in reliability in operation of the apparatus, system, and device.

It should be appreciated that the drawings herein are illustrative of various aspects of the embodiments herein, not exhaustive of the present disclosure. For example, FIGS. 4 and 5 are simplified for considerations of clarity. While not shown, it should be appreciated that FIGS. 4 and 5 may include under bump metallization (UBM), underfill materials, and other flip chip components and attributes.

The several embodiments described herein are solely for the purpose of illustration. Persons in the art will recognize from this description that other embodiments may be practiced with modifications and alterations limited only by the claims.

What is claimed is:

1. A method comprising:
providing a substrate having a conductive bump pad on a first surface of the substrate; and
forming a dome shaped conductive area on a center area of the conductive bump pad.

2. The method of claim 1, wherein the dome shaped conductive area does not extend to a peripheral edge of the conductive bump pad.

3. The method of claim 1, further comprising a plurality of conductive bump pads.

4. The method of claim 1, further comprising:
applying a resist material to the center area of the conductive bump pad and to areas surrounding the conductive bump pad;
building up peripheral sidewalls of the metal pad between the resist material; and
removing the resist material, wherein the dome shaped conductive area is formed on the center area of the conductive bump pad between the built-up sidewalls of the conductive bump pad.

5. The method of claim 1, further comprising forming a solder resist opening above the dome shaped conductive area, wherein solder resist material is adjacent to and surrounding the dome shaped conductive area.

6. The method of claim 5, further comprising:
placing solder in the solder resist opening on top of the dome shaped conductive area; and
reflowing the solder to form a solder bump in the solder resist opening.

7. The method of claim 5, wherein the dome shaped conductive area is confined to an extent of the solder resist opening.

8. The method of claim 5, wherein the solder resist opening is about 70 micrometers (μm) or less in diameter.

9. The method of claim 1, wherein the conductive bump pad is substantially flat from an outer edge of the dome shaped conductive area to a peripheral edge of the conductive bump pad.

10. The method of claim 1, wherein the dome shaped conductive area is formed by an electrolytic copper (Cu) plating process using a plating solution that chemically controls the formation of the dome shaped conductive area.

11. An apparatus comprising:
a substrate having a conductive bump pad on a first surface of the substrate;
a dome shaped conductive area on a center area of the conductive bump pad; and
a solder resist opening above the dome shaped conductive area, wherein solder resist material is adjacent to and surrounding the dome shaped conductive area.

12. The apparatus of claim 11, further comprising a solder bump located in the solder resist opening on top of the dome shaped conductive area, wherein an upper portion of the solder bump extends above an upper surface of the solder resist opening.

13. The apparatus of claim 11, wherein the dome shaped conductive area is formed by an electrolytic copper (Cu) plating process using a plating solution that chemically controls the formation of the dome shaped conductive area.

14. The apparatus of claim 11, wherein the dome shaped conductive area is confined to coincide with the solder resist opening.

15. The apparatus of claim 11, wherein the solder resist opening is about 70 micrometers (μm) or less in diameter.

16. The apparatus of claim 11, wherein the conductive bump pad is substantially flat from an outer edge of the dome shaped conductive area to a peripheral edge of the conductive bump pad.

17. A system comprising:
a substrate having a conductive bump pad on a first surface of the substrate;
a dome shaped conductive area on a center area of the conductive bump pad;
a solder resist opening above the dome shaped conductive area, wherein solder resist material is adjacent to and surrounding the dome shaped conductive area;
a solder bump located in the solder resist opening on top of the dome shaped conductive area, wherein an upper portion of the solder bump extends above an upper surface of the solder resist opening; and
an integrated circuit (IC) device attached to the solder bump.

18. The system of claim 17, wherein the dome shaped conductive area is formed by an electrolytic copper (Cu) plating process using a plating solution that chemically controls the formation of the dome shaped conductive area.

19. The system of claim 17, wherein the dome shaped conductive area is confined to coincide with the solder resist opening.

20. The system of claim 17, wherein the solder resist opening is about 70 micrometers (μm) or less in diameter.

21. The system of claim 17, wherein the conductive bump pad is substantially flat from an outer edge of the dome shaped conductive area to a peripheral edge of the conductive bump pad.

22. The system of claim 17, wherein the IC is a microprocessor.
